(19) United States
(12) Patent Application Publication
(10) Pub. No.: US 2006/0073627 A1
(43) Pub. Date: Apr. 6, 2006

(54) Probe for a scanning probe microscope and method for fabricating same

(75) Inventors: Young-Geun Park, Seoul (KR); Kyu-Ho Hwang, Seoul (KR)

Correspondence Address: BACON & THOMAS, PLLC, 625 SLATERS LANE, FOURTH FLOOR, ALEXANDRIA, VA, 22314, US

(73) Assignee: M2N INC., Gyeonggi-do (KR)

(21) Appl. No.: 10/519,671

(22) PCT Filed: Mar. 31, 2004
(86) PCT No.: PCT/KR04/00741

§ 371 Date: Jan. 6, 2005

(51) Int. Cl. H01L 21/00; C23F 1/00

(52) U.S. Cl. 438/52; 216/41; 216/2

(57) ABSTRACT

A method for fabricating a probe for a scanning probe microscope, wherein the probe includes a mounting block, a cantilever and a tip, includes the steps of: forming a first mask to define a pattern for the tip and a second mask to define a pattern for the cantilever on an SOI wafer having a handle layer containing {100} single-crystalline silicon, an insulating layer and a device layer containing {111} single-crystalline silicon; etching the device layer by using the first and the second masks; forming a sidewall passivation layer on the device layer; etching the device layer by using the first mask to form the tip; etching the handle layer by using a third mask to define a pattern for the mounting block. By using the method, a probe made of {111} single-crystalline silicon can be fabricated with high yield.

### TECHNICAL FIELD

The present invention relates to a probe for a scanning probe microscope and a fabricating method thereof; and, more particularly, to a probe having a microprobe and a fabricating method thereof using an SOI wafer including a {111} single-crystalline silicon layer.

### BACKGROUND ART

A scanning probe microscope (SPM) operates while scanning a surface of a sample with a probe, wherein the probe generally includes a mounting block, a cantilever connected to the mounting block and a probe tip attached to one end of the cantilever.

FIG. 1 shows an exemplary operation of an SPM. As illustrated in FIG. 1, if a probe tip 110 attached to a cantilever 120 scans a surface of a sample 130, an interaction between the probe tip 110 and the sample 130 is detected and, further, the detected result is converted into an image. In other words, a laser beam generated from a light source 150 is irradiated on an upper surface of the cantilever 120. Further, if the probe tip 110 vertically moves along a bent of the surface of the sample 130, a reflection angle formed between a laser beam irradiated on the upper surface of the cantilever 120 and a reflected laser beam is changed. Accordingly, a position-sensitive detector 140 provided in a traveling direction of the reflected laser beam detects a movement of the reflected laser beam and, further, the detected result is converted into an image.

A performance of the SPM shown in FIG. 1 depends largely on characteristics of the probe tip 110. The characteristics of the probe tip 110 can be evaluated in terms of a height, a radius of a tip apex, an aspect ratio of the probe tip or the like.

Especially, the aspect ratio of the probe tip is a critical feature to determine a detection resolution of the SPM. For example, as illustrated in FIGS. 2A and 2B, in case the probe scans a right-angled bent of the surface of the sample 130 and, then, the result thereof is converted into an image, a greater aspect ratio of the probe tip 110 enables a more precise visualization of the step of the surface of the sample 130.

Meanwhile, as disclosed in U.S. Pat. Nos. 6,504,152 and 6,066,265, most of the conventional probe tips have been fabricated by performing a wet etching process or an isotropic dry etching process on a {100} crystal face of {100} single-crystalline silicon. However, in case such processes are employed, it is difficult to obtain a silicon probe tip of a high aspect ratio. Therefore, in order to fabricate the probe tip of a high aspect ratio, there may be employed a method for sharpening an end portion of a silicon probe tip by performing an additional process using, e.g., a focused ion beam (FIB).

However, if {111} single-crystalline silicon is etched by using a wet etching method or the like, the probe tip having a {111} crystal face and a high aspect ratio can be fabricated (see, Park, J. H., Park, K. D., Paik, S. J., Koo, K. I., Choi, B. D., Kim, J. P., Park, S. J., Jung, I. W., Ko, H. H., and Cho, D. I., “Extremely Sharp 111-Bound, Single-crystalline Silicon Nano Tips,” International Journal of Computational Engineering Science (IJCES), vol. 4, no. 2, pp. 327-330, September. 2003.) For example, if one surface forming the probe tip is so wet-etched as to have a {111} crystal face and, further, other surfaces forming the probe tip are fabricated by a dry etching method, it is possible to obtain the probe tip having a high aspect ratio of 3:1 to 5:1.

FIG. 3 depicts an exemplary probe tip fabricated by using {111} single-crystalline silicon, wherein the probe tip is fabricated by using one {111} surface defined by the wet etching and two vertical surfaces defined by the dry etching. As illustrated in FIG. 3, a cone angle of the probe tip is chosen to be 19.5° C. formed by a {111} surface 310 and a vertical surface 320. In this case, a relationship between a height h of the probe tip and a width d of a base portion of the probe tip is defined as:

$$h = \frac{d}{tan ( 19.5 ° )} ≅ 2.82 \times d , \qquad Eq . ( 1 )$$

herein an aspect ratio (h:d) of the probe tip illustrated in FIG. 3 is about 3:1, as can be obtained from Eq. (1).

However, there has not been developed yet a method for fabricating a probe for a scanning probe microscope, the probe having, e.g., the probe tip illustrated in FIG. 3. Accordingly, the present invention provides a fabricating method of a probe for a scanning probe microscope, the probe including a probe tip, a cantilever and a mounting block supporting the cantilever.

### DISCLOSER OF INVENTION

It is, therefore, an object of the present invention to provide a probe for a scanning probe microscope and a fabricating method thereof, i.e., a probe and a fabricating method thereof using an SOI wafer including a {111} single-crystalline silicon layer, which has a high yield and a stability.

In accordance with one aspect of the invention, there is provided a method for fabricating a probe for a scanning probe microscope, comprising the steps of: (a) forming a first mask for defining a probe tip on a wafer including a handle layer on which a mounting block of the probe is formed, an insulating film on the handle layer and a device layer in which a cantilever and a probe tip of the probe are formed; (b) forming a second mask for defining the cantilever of the probe on the device layer and the first mask patterns; (c) etching the device layer by using the first and the second mask patterns; (d) removing the second mask; (e) forming a sidewall passivation layer on a sidewall of the device layer; (f) etching the device layer by using the first mask pattern while leaving a thickness thereof as much as a thickness of the cantilever; (g) removing the first mask; (h) forming the probe tip by performing a wet etching process on the device layer; (i) removing the sidewall passivation layer; (j) forming a third mask for defining the mounting block of the probe on a lower surface of the handle layer; (k) etching the handle layer by using the third mask as a pattern; and (l) removing the third mask.

In accordance with another aspect of the invention, there is provided a probe fabricated by using the method for fabricating a probe for a scanning probe microscope.

### BRIEF DESCRIPTION OF DRAWINGS

The above and other objects and features of the present invention will become apparent from the following description of preferred embodiments given in conjunction with accompanying drawings, in which:

FIG. 1 is a diagram for explaining an operation of a scanning probe microscope;

FIGS. 2A and 2B provide diagrams illustrating an example in which a result image becomes different depending on an aspect ratio of a probe tip in case a scanning probe microscope produces an image obtained by detecting a bent of a sample;

FIG. 3 shows a configuration of a probe tip of a probe fabricated by using {111} single-crystalline silicon;

FIG. 4 depicts a diagram describing an exemplary probe fabricated by using a method for fabricating a probe in accordance with a preferred embodiment of the present invention;

FIG. 5 presents a top view of a mask used in the method for fabricating a probe in accordance with the preferred embodiment of the present invention;

FIGS. 6A to 6O represent cross-sectional views of probe structures fabricated by performing steps of the method for fabricating a probe in accordance with the preferred embodiment of the present invention; and

FIGS. 7A and 7B offer side views of a probe tip fabricated by using the method for fabricating a probe in accordance with the preferred embodiment of the present invention.

### BEST MODE FOR CARRYING OUT THE INVENTION

Hereinafter, preferred embodiments of the present invention will be described in detail with reference to the accompanying drawings.

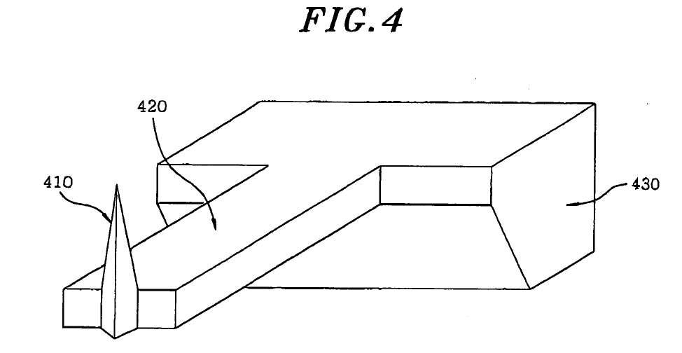

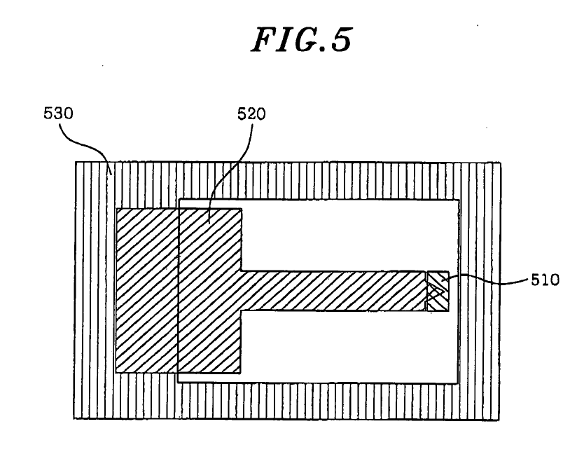

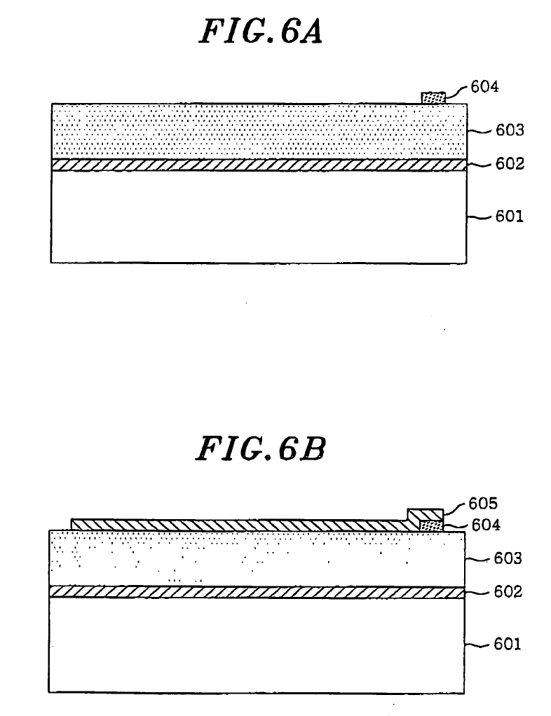

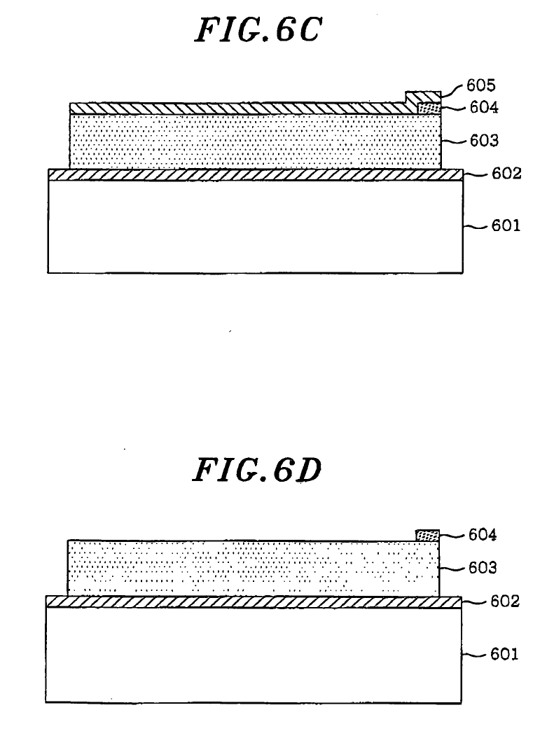

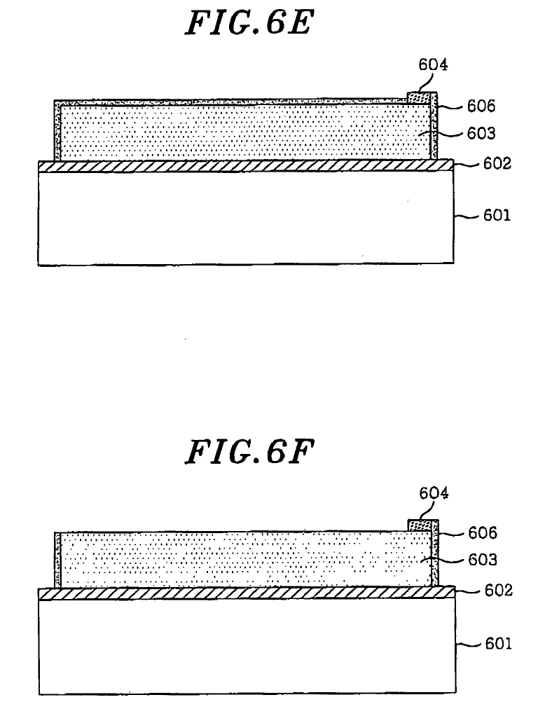

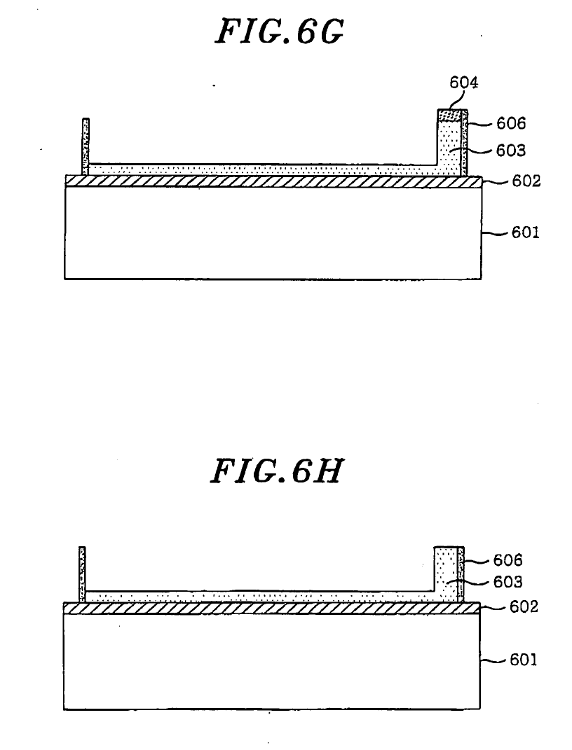

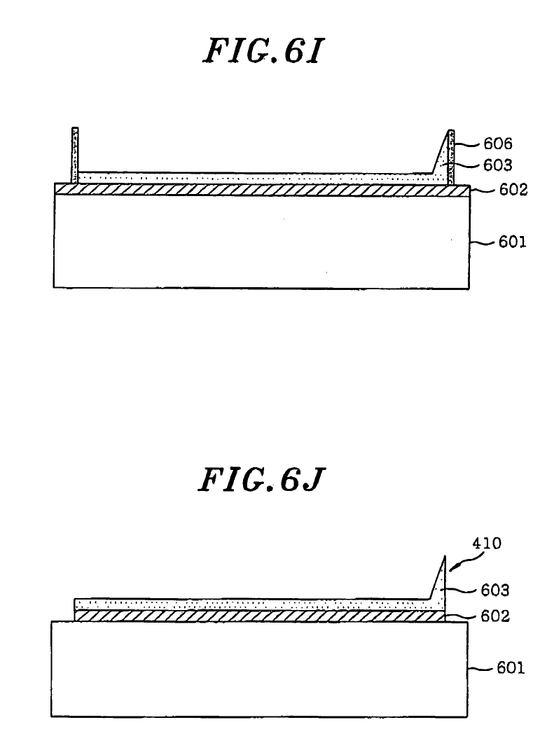

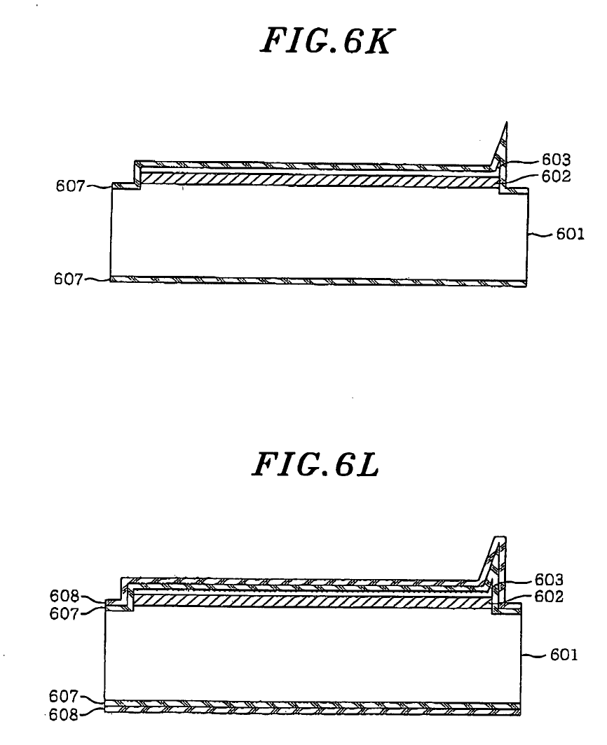

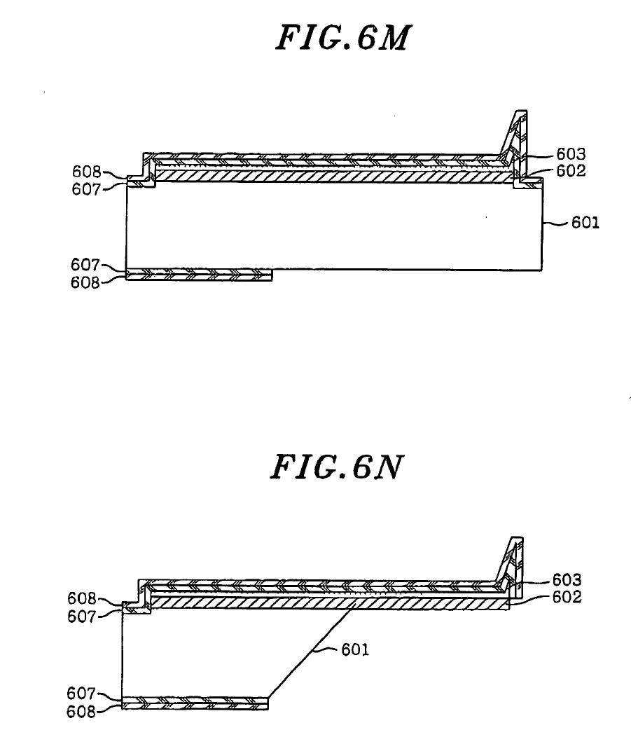

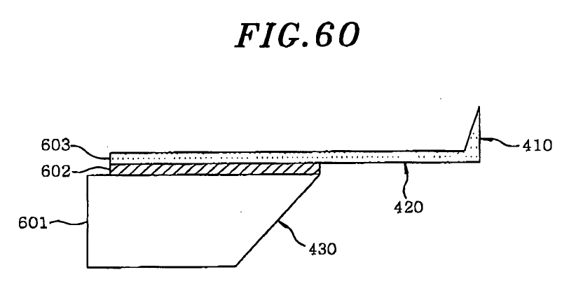

FIG. 4 describes an exemplary probe fabricated by using a method for fabricating a probe in accordance with a preferred embodiment of the present invention. The probe illustrated in FIG. 4 includes a mounting block 430, a cantilever 420 protrudingly formed at one surface of the mounting block and a probe tip 410 formed at one end of the cantilever 420. Hereinafter, the method for fabricating a probe in accordance with the preferred embodiment of the present invention will be described in detail with reference to FIGS. 5 and 6A to 6O, wherein the probe illustrated in FIG. 4 will be provided as an example.

The method for fabricating a probe in accordance with the preferred embodiment of the present invention is carried out by using a silicon on insulator (SOI) wafer. The SOI wafer is formed by joining two wafers with an insulating film. The present invention uses the SOI wafer comprised of a {100} single-crystalline silicon layer, an insulating film laminated thereon and a {111} single-crystalline silicon layer laminated on the insulating layer.

As shown in FIG. 6A, in the method for fabricating a probe in accordance with the preferred embodiment of the present invention, the SOI wafer including a {100} single-crystalline silicon layer 601 (hereinafter, referred to as ‘handle layer’), an insulating film 602 and a {111} single-crystalline silicon layer 603 (hereinafter, referred to as ‘device layer’) is used. Each thickness of the handle layer, the insulating film 602 and the device layer 603 is preferably, e.g., 25 μm, 2 μm and 300 μm, respectively.

The layer on an upper surface of the SOI wafer is a first mask 604 serving as a hard mask during a silicon dry etching process to be performed later. A thickness of the first hard mask layer 604 should be thick enough to endure a deep silicon reactive ion etching (DRIE) process to be carried out later. For example, a thickness of a silicon oxide film 604 is preferably 1 μm.

In FIG. 6A, the first mask 604 can be deposited by performing following processes, for example. In other words, after a wet thermal oxide film is deposited in an atmosphere of H₂O by using a chemical vapor deposition method, a first photolithographic process is performed to define a portion of the probe tip 410 to be formed later. Next, the thermal oxide film is patterned by using an oxide film dry etcher using a plasma and, then, a remaining photosensitive film is removed by using an O₂ plasma method or a mixed solution of sulfuric acid and hydrogen peroxide. For instance, the first mask 604 formed after the patterning process can have a shape of a mask 510 illustrated in FIG. 5 when the structure shown in FIG. 6A is seen from an upper surface of the device layer 603.

Thereafter, as described in FIG. 6B, a second mask 605 is formed on the device layer 603 and the first mask 604. The second mask 605 can be formed as follows. In other words, a tetraethylorthosilicate (TEOS) oxide film is firstly deposited by using a plasma-enhanced chemical vapor deposition (PECVD) method and, then, a photoresist (PR) layer is coated on the TEOS oxide film. Further, after the PR layer is patterned by performing a second photolithographic process for defining portions of the cantilever 420 and the mounting block 430 that will be formed later, the TEOS oxide film is patterned based on the PR pattern by using the dry etching method. Next, the PR layer that remains after the patterning process is removed by using the O₂ plasma method or the mixed solution of sulfuric acid and hydrogen peroxide. For example, the second mask 605 formed after the patterning process can have a shape of a mask 520 illustrated in FIG. 5 when the structure shown in FIG. 6B is seen from the upper surface of the device layer 603. Further, the second mask 605 can be formed of a PR layer or a metal film containing Cr or Al, besides the TEOS oxide film.

Thereafter, as illustrated in FIG. 6C, a first DRIE process is performed by using the already formed first and second masks 604 and 605 in order to determine a final shape of the cantilever and form two vertical sidewalls among three surfaces forming the probe. The DRIE process can be performed as follows, for example. That is, a polymer deposition step, a polymer etching step and a silicon etching step are sequentially performed for 3 seconds, 5 seconds and 3 seconds, respectively. Herein, the silicon etching step is carried out in an atmosphere of SF₆ gas. In this case, the device layer 603 is etched so that an insulating layer 602 of the SOI wafer is exposed, wherein an etching depth is preferably about 25 μm.

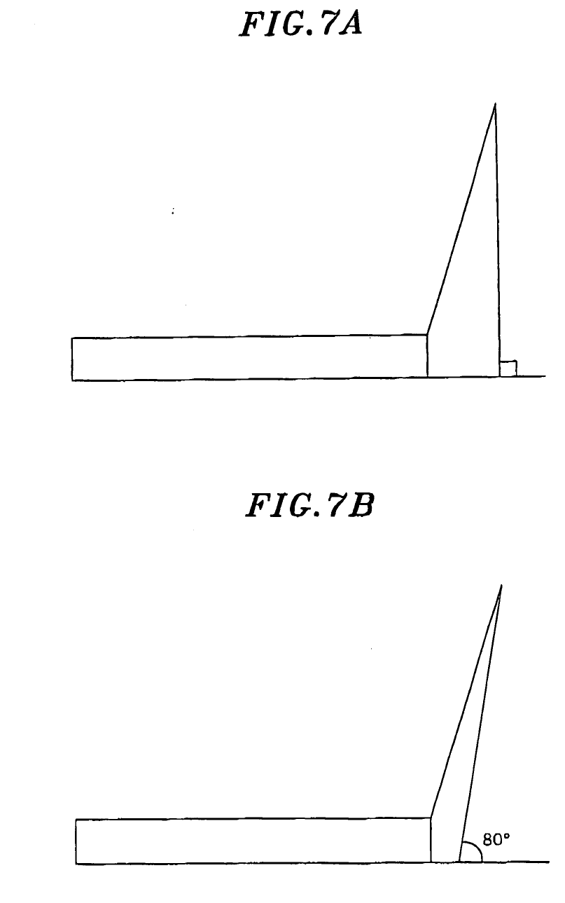

Moreover, an aspect ratio of the probe tip 410 to be finally formed can be varied within a range of about 3:1 to 5:1 by changing an angle formed by an etched side surface of the device layer 603 and the exposed insulating layer 602 within a range of 75° to 90° while varying DRIE etching conditions. For example, FIG. 7A shows a shape of a probe tip obtained in case an angle formed by the device layer 603 and the insulating layer 602 is 90°. The probe tip illustrated in FIG. 7A has an aspect ratio of about 3:1. Further, FIG. 7B illustrates a shape of a probe tip obtained in case an angle formed by the device layer 603 and the insulating layer 602 is 80°. In this case, the probe tip has an aspect ratio of about 5:1.

Next, a process for removing the polymer and the first mask 605 that remain after the first DRIE process is performed (see FIG. 6D). The process for removing the polymer can be carried out by soaking a wafer after processing in an O₂ plasma atmosphere in the mixed solution of sulfuric acid and hydrogen peroxide for more than about an hour so that the polymer can be completely removed.

Thereafter, a sidewall passivation film 606 for protecting a sidewall of the device layer 603 is formed (see FIG. 6E). In this process, the sidewall passivation film 606 is formed of a wet thermal oxide film or a silicon nitride film. For instance, it is formed by growing the wet thermal oxide film at 1000° C. in an atmosphere of H₂O . A growth rate of the thermal oxide film becomes different depending on a crystallographic direction of silicon. In this process, it is preferable to form a thermal oxide film having a thickness of 5000 Å on the basis of a surface of the device layer 603.

Then, as a preparation step for etching a sacrificial layer, the TEOS oxide film and the thermal oxide film that cover an upper surface of the device layer 603 among the sidewall passivation film 606 are removed by a dry etching (see FIG. 6F). In this case, the thermal oxide film, i.e., the first mask 604, needs to be prevented from being removed. Next, a second DRIE process for forming a thickness of a cantilever and a tip is performed by using the first mask 604 (see FIG. 6G). An etching depth by the second DRIE process is preferably about 18 μm to 22 μm. Since a thickness of the cantilever 420 to be finally formed determines a resonance frequency of a probe and a spring constant of the cantilever 420, the device layer 603 is etched so that the required characteristics for using the probe can be provided. In other words, a difference between the etching depths of the first and the second DRIE processes, which are illustrated in FIGS. 6C to 6G, becomes a thickness of the cantilever 420 of the probe.

Thereafter, the first mask 604 covering an upper portion of the probe tip 410 to be finally formed is removed (see FIG. 6H) and, then, a silicon wet etching process is performed to form the probe tip 410 (see FIG. 6I). At this time, although an upper surface of a portion where the cantilever 420 (see FIG. 4) is formed among the device layer 603 is exposed to an etching solution, such surface is a {111} plane of {111} single-crystalline silicon and, thus, an etching rate is slower then other crystal planes by 50 times to 100 times. On the other hand, in a portion where the probe tip 410 is formed among the device layer 603, the etching is performed on a new {111} plane of probe tip 410. The wet etching can be carried out by using an alkali solution capable of etching silicon, such as a KOH solution or a TMAH (tetramethyl ammonium hydroxide) solution. In other words, for example, the wet etching can be performed by using the KOH (potassium hydroxide) solution of 44 wt % at 65° C. Such condition is a solution condition having a lowest etching rate with respect to the {111} surface, and the wet etching process is performed for 20 to 25 minutes under such condition. In addition, isopropyl alcohol can be added to the KOH solution used in the wet etching process in order to prevent hydrogen bubbles, which are generated during the wet etching process and remain on a surface of an etching target, from interrupting a progress of the etching process.

Next, as illustrated in FIG. 6J, the remaining sidewall passivation film 606 is removed. The sidewall passivation film 606 can be removed by using, e.g., a BOE (buffered oxide etchant) or a HF (hydrofluoric acid) solution. By removing the sidewall passivation film 606, a fundamental shape of the probe tip 410 is formed.

In order to sharpen the probe tip 410 formed as illustrated in FIG. 6J, the oxidation process is performed on a surface of a wafer including the device layer 603 (see FIG. 6K) and, then, a silicon nitride film 608 is deposited thereon (see FIG. 6L). At this time, the thermal oxide film is deposited with a thickness ranging from 5000 Å to 1 μm depending on a sharpening degree. Further, a thickness of the silicon nitride film 608 deposited on the silicon oxide film 607 is preferably, e.g., 1500 Å.

Thereafter, by patterning the silicon oxide film 607 and the silicon nitride film 608 that are deposited on a lower surface of the handle layer 401, a third mask is formed to define a portion where the mounting block 430 for supporting the cantilever 420 is formed (see FIG. 6M) . For example, the third mask can have a shape of the mask 530 illustrated in FIG. 5 when the structure shown in FIG. 6M is seen from the lower surface of the handle layer 601.

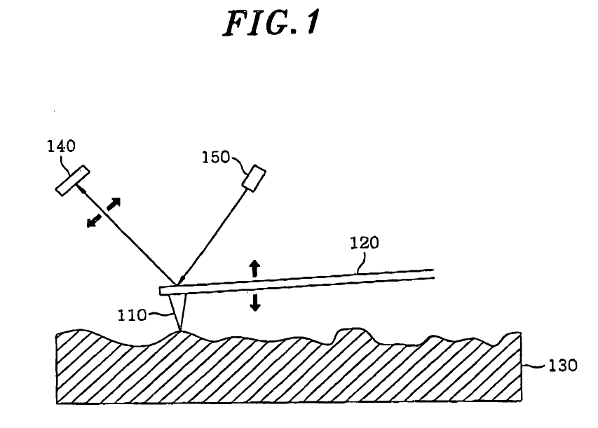

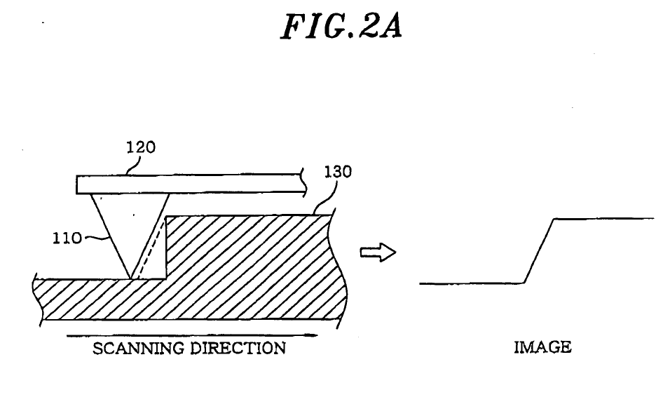

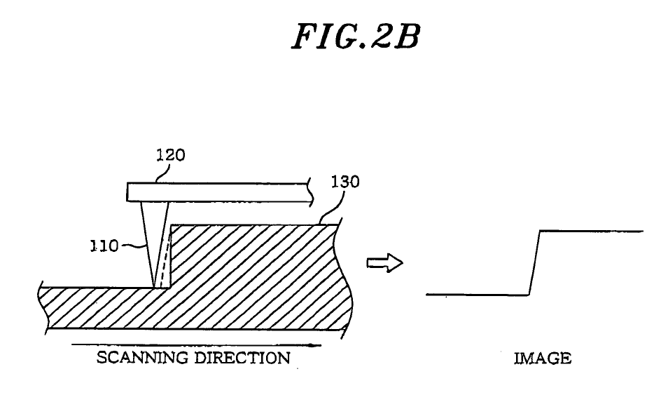

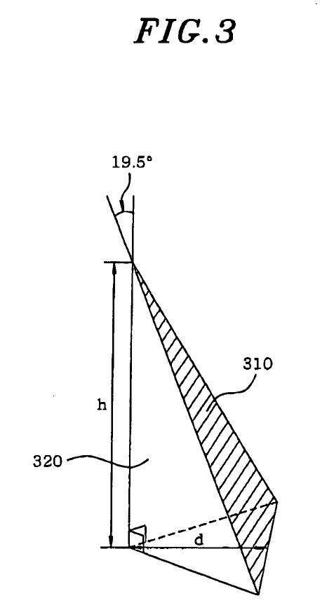

Then, a part of the handle layer 601 is removed by using a wet etching method or a dry etching method using the DRIE with the third mask as a pattern, thereby generating a desired-shaped mounting block (see FIG. 6N). Finally, the remaining silicon nitride film 608 and silicon oxide film 607 are removed and, further, an insulating film 602 of the SOI wafer, which covers a lower surface of the cantilever 420, is removed, so that a final probe structure is obtained (see FIG. 60). The lower surface of the cantilever 420 of the probe structure illustrated in FIG. 60 forms a surface of the scanning probe microscope on which a laser beam reflected, which has been described with reference to FIG. 1.

In the fabricating process of the probe tip described with reference to FIGS. 6K to 6N, the oxidation process are performed so as to sharpen the probe tip 410 illustrated in FIG. 6J. However, such process can be omitted from the entire processes, if necessary. Further, in the fabricating process of the probe tip described with reference to FIG. 6L to 6N, the silicon nitride film 608 is deposited on the both sides of wafers. However, the silicon nitride film 608 serves as a mask for defining the mounting block 430 of the probe tip and thus can be selectively deposited only on the lower surface of the handle layer 601.

While the invention has been shown and described with respect to the preferred embodiments, it will be understood by those skilled in the art that various changes and modifications may be made without departing from the spirit and scope of the invention as defined in the following claims.

1. A method for fabricating a probe for a scanning probe microscope, comprising the steps of:
(a) forming a first mask pattern for defining a probe tip on a wafer including a handle layer on which a mounting block of the probe is formed, an insulating film on the handle layer and a device layer in which a cantilever and a probe tip of the probe are formed;
(b) forming a second mask for defining the cantilever of the probe on the device layer and the first mask;
(c) etching the device layer by using the first and the second mask as patterns;
(d) removing the second mask;
(e) forming a sidewall passivation layer on a sidewall of the device layer;
(f) etching the device layer by using the first mask as a pattern while leaving a thickness thereof as much as a thickness of the cantilever;
(g) removing the first mask;
(h) forming the probe tip by performing a wet etching process on the device layer;
(i) removing the sidewall passivation layer;
(j) forming a third mask for defining the mounting block of the probe on a lower surface of the handle layer;
(k) etching the handle layer by using the third mask as a pattern; and
(l) removing the third mask.

2. The method of claim 1, wherein the wafer is an SOI (silicon on insulator) wafer including a device layer containing {111} single-crystalline silicon, an insulating oxide film and a handling layer containing {100} single-crystalline silicon.

3. The method of claim 1, wherein the first mask uses a wet thermal oxide film or a TEOS oxide film.

4. The method of claim 1, wherein the second mask is a TEOS oxide film, a metal film using Cr or Al, or a PR (photoresist) layer.

5. The method of claim 1, wherein in the step (c), the device layer is etched by employing a dry etching method using a DRIE (deep reactive ion etching).

6. The method of claim 1, wherein in the step (c), an aspect ratio of the probe tip is determined depending on an angle formed by the sidewall of the etched device layer and an upper surface of the insulating layer.

7. The method of claim 1, wherein the sidewall passivation film is formed by growing a wet thermal oxide film or a silicon nitride film on the sidewall of the device layer.

8. The method of claim 1, wherein in the step (h), the probe tip is formed by defining a {111} surface by employing a wet etching method using a KOH solution, a TMAH (tetramethyl ammonium hydroxide) solution or the like.

9. The method of claim 1, wherein in the step (j), the third mask is formed by using a silicon oxide film or a silicon nitride film.

10. The method of claim 1, wherein in the step (k), the handle layer is etched by using a wet etching method or a dry etching using the DRIE.

11. The method of claim 1, further comprising the step of oxidation process on a surface of the device layer to sharpen the probe tip after performing the step (i).

12. A probe for a scanning probe microscope fabricated by using the method of claim 1.

13. A probe for a scanning probe microscope fabricated by using the method of claim 2.

14. A probe for a scanning probe microscope fabricated by using the method of claim 3.

15. A probe for a scanning probe microscope fabricated by using the method of claim 4.

16. A probe for a scanning probe microscope fabricated by using the method of claim 5.

17. A probe for a scanning probe microscope fabricated by using the method of claim 6.

18. A probe for a scanning probe microscope fabricated by using the method of claim 7.

19. A probe for a scanning probe microscope fabricated by using the method of claim 8.

20. A probe for a scanning probe microscope fabricated by using the method of claim 9.
